(19) United States
(12) Patent Application Publication
(10) Pub. No.: US 2026/0086141 A1
(43) Pub. Date: Mar. 26, 2026

(54) CIRCUIT DETECTION AND LIGHT EMITTING DIODE CONTROLLERS

(71) Applicant: Texas Instruments Incorporated, Dallas, TX (US)

(72) Inventors: Wentao Xu, Wuhan (CN); Yurong Zhang, Shanghai (CN); Shangquan Liang, Shanghai (CN); Yichao Tang, Shanghai (CN)

(21) Appl. No.: 18/896,511

(22) Filed: Sep. 25, 2024

(51) Int. Cl. G01R 31/28; H05B 45/397

(52) U.S. Cl. CPC G01R 31/2837; H05B 45/397

(57) ABSTRACT

An example detection circuitry includes a bypass circuitry configured to selectively bypass a series of light emitting diodes from a light emitting diode driver, a first voltage detection circuitry configured to compare a voltage at a first terminal of the series of light emitting diodes to a first reference voltage and output a first indication of the comparison, and a logic circuitry configured to output a circuit type based on the first indication.

### TECHNICAL FIELD

This description relates generally to electronic circuits and, more particularly, to circuit detection and light emitting diode controllers.

### BACKGROUND

A driver circuit provides electrical power to one or more electrical components. For example, a light emitting diode (LED) driver circuit provides power to one or more LEDs. The operation of electrical components powered by a driver circuit may be controlled by a controller. For example, an LED controller may control the on/off state, brightness, color, etc. of a string of LEDs and/or may control individual LEDs or groups of LEDs in a string of LEDs. A string of LEDs may include one or more LEDs connected in series and/or in parallel.

### SUMMARY

For circuit detection and light emitting diode controllers, an example detection circuitry includes a bypass circuitry configured to selectively bypass/disconnect a series of light emitting diodes from a light emitting diode driver; a first voltage detection circuitry configured to compare a voltage at a first terminal of the series of light emitting diodes to a first reference voltage and output a first indication of the comparison, and a logic circuitry configured to output a circuit type based on the first indication. Other examples are described.

For circuit detection and light emitting diode controllers, an example detection circuitry includes a switch having a first terminal configured to be coupled to a first terminal of a series of light emitting diodes and a second terminal to be coupled to a second terminal of the series of light emitting diodes. The detection circuitry includes a first comparator having a first input terminal coupled to the second terminal of the series of light emitting diodes and a second terminal coupled to a first reference voltage. The detection circuitry includes a second comparator having a first input terminal coupled to the first terminal of the series of light emitting diodes and a second terminal coupled to a second reference voltage. The detection circuitry includes a logic circuitry having a first input terminal coupled to an output of the first comparator, a second input terminal coupled to an output of the second comparator, and the logic circuitry configured to output an indication of a circuit type of a controller of the series of light emitting diodes. Other examples are described.

For circuit detection and light emitting diode controllers, an example light emitting diode controller includes a current source; a current sink, a driver coupled to the current source and the current sink. The light emitting diode controller includes a transistor coupled to an output of the driver. The light emitting diode controller includes a switch having a first terminal to be coupled to an anode of a series of light emitting diodes and a second terminal configured to be coupled to a cathode of the series of light emitting diodes. The light emitting diode controller includes a first comparator having a first input terminal coupled to the cathode of the series of light emitting diodes and a second terminal coupled to a first reference voltage. The light emitting diode controller includes a second comparator having a first input terminal coupled to the anode of the series of light emitting diodes and a second terminal coupled to a second reference voltage. The light emitting diode controller includes a logic circuitry having a first input terminal coupled to an output of the first comparator, a second input terminal coupled to an output of the second comparator, and an output to output an indication of a circuit type of a controller of the series of light emitting diodes to the current source and current sink. Other examples are described.

### BRIEF DESCRIPTION OF THE DRAWINGS

FIG. 1 illustrates an example circuit for driving and controlling light emitting diodes (LEDs) as disclosed herein.

FIG. 2 illustrates another example circuit for driving and controlling LEDs as disclosed herein.

FIG. 3 is a truth table illustrating the logic of the logic circuitry of FIG. 1 and/or FIG. 2.

FIG. 4 is a flowchart illustrating the operation of the LED dot-controller of FIG. 1 and/or FIG. 2.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

When two circuits interact with each other, the design and structure of one circuit may influence the operation of the other circuit. For example, a driver circuit for LEDs may be implemented as a current-sink-type LED driver, a current-source-type LED driver, etc. An LED controller controlling LEDs driven by such a driver may need to modify operation depending on the type of the driver circuit. For example, an LED controller may include a series of gate drivers connected to a series of transistors (e.g., field effect transistors (FETs)) to control a series of LEDs. Furthermore, the gate drivers may be powered by internal current sources and internal current sinks of the LED controller. The amount of current source relative to the amount of current sink varies depending on the type of LED driver and the way in which the power is supplied to the LEDs by the current driver. If the current source and the current sink are not balanced properly based on the type of LED driver circuit, leakage current may cause the LEDs to be partially turned on even when the LED controller is controlling the LEDs to be off. The leakage current due to compensation mismatching (e.g., an imbalance between the current sourced in the circuitry and the current sunk in the circuitry) will be summed up to a large amount through the first or last LED of the LED string, leading to undesired LED brightness and color cast (e.g., the lighting hue, color, etc. output by the LED).

Typically, a front-end LED driver works as a current regulator to supply current through the LED string. Each LED of the LED string should see zero current if the LED driver is disabled. For current-sink-type LED drivers, such as floating buck drivers, the anode of the top LED of the LED string is connected to the system VIN. When a ratio N of the internal current source is less than a ratio K of the internal current sink of the LED dot-controller (e.g., a controller that can control the operation of individual and/or groups of LEDs), the mismatching current will flow into the LED string from VIN to the internal current sink of the dot-controller. However, for current-source type LED drivers, such as a buck driver, the cathode of a bottom LED of an LED string is connected to ground. Hence, when the ratio N of the internal current source is greater than the ratio K of the internal current sink of the LED dot-controller, the mismatching current will flow into the LED string from the internal current source of the dot-controller to the ground.

An example LED controller described herein utilizes circuit to detect the circuit type of the LED driver connected to a series of LEDs and adjusts the internal current source and internal current sink of the LED dot-controller to compensate for the detected circuit type. As used herein, a series of LEDs includes any arrangement of multiple LEDs that may be connected in series and/or in parallel such as a string of LEDs, a plurality of LEDs connected in series, a matrix of LEDs connected in rows and columns or other configurations, etc. While the example disclosed herein utilize the circuit detect in the context of an LED dot-controller, the detection circuit may be utilized in other applications in which circuit detection and/or compensation may be desired.

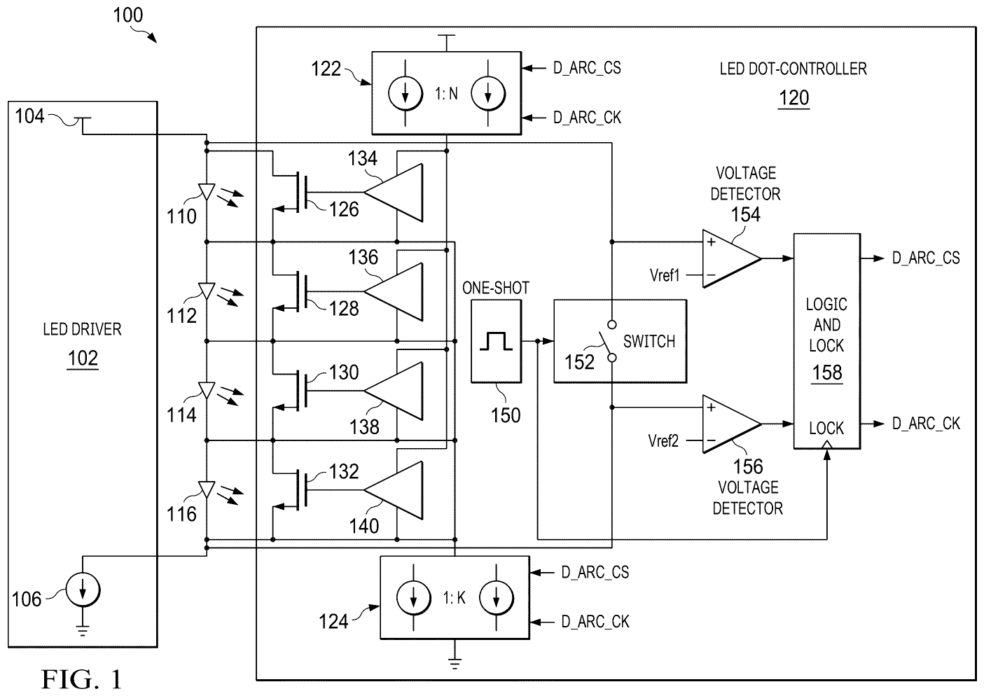

FIG. 1 illustrates an example circuit 100 for driving and controlling light emitting diodes (LEDs). The example circuit 100 includes an LED driver 102 that includes an input voltage 104 and a current sink 106. The example circuit 100 further includes a series of LEDs 110-116. Further, the example circuit 100 includes an LED dot-controller 120.

The example LED driver 102 is a current sink-type LED driver. The example input voltage 104 is coupled to an anode of the first LED 110. A first terminal of the current sink 106 is coupled to a cathode of the fourth LED 116 and a second terminal of the current sink 106 is coupled to ground. The example LED driver 102 of the illustrated example is an integrated circuit. Alternatively, any other structure may be utilized to implement the LED driver 102.

The LEDs 110-116 are LEDs for matrix lighting (e.g., lighting elements that utilize a plurality of LEDs to provide a lighting source such as a grid, a row, etc.) such as stage lighting, surgical lighting, lighting used in machine vision, etc. Alternatively, the LEDs may be any type of LEDs. For example, the LEDs 110-116 may be individually controlled LEDs in which the brightness, color, etc. may be controlled. The example LEDs 110-116 are connected in series such that the first LED 110 includes an anode connected to the input voltage 104 and a cathode connect to an anode of the second LED 112. The second LED 112 includes a cathode connected to an anode of the third LED 114. The third LED 114 includes a cathode connected to an anode of the fourth LED 116. The fourth LED 116 includes a cathode connected to a first terminal of the current sink 106 of the LED driver 102. The current sink 106 includes a second terminal connected to ground.

The example LED dot-controller 120 includes an adjustable current source 122, an adjustable current sink 124, a set of transistors 126-132, a set of drivers 134-140, a pulse generator circuitry 150, a bypass circuitry 152, a first detection circuitry 154, a second voltage detection circuitry 156, and a logic circuitry 158. While the LED dot-controller 120 is a dot-controller, any type of light emitting diode controller may be utilized.

The adjustable current source 122 of the illustrated example is adjustable in that the amount of current sourced by the adjustable current source 122 can be adjusted (e.g., adjusted in response detection of a circuit type of the LED driver 102). To facilitate adjustment, the example adjustable current source 122 includes an adjustable current mirror in which a number of current mirroring branches can be selected to control the amount of current sourced. An output of the example current mirror is connected to a positive voltage terminal of each of the drivers of the set of drivers 134-140.

The adjustable current sink 124 of the illustrated example is adjustable in that the amount of current sunk by the adjustable current sink 124 can be adjusted. To facilitate adjustment, the example adjustable current sink 124 includes an adjustable current mirror in which a number of current mirroring branches can be selected to control the amount of current sunk. An input of the example current mirror is connected to a negative voltage terminal of each of the drivers of the set of drivers 134-140.

The example set of transistors 126-132 are field effect transistors (FETs) that each include a drain connected to an anode of a respective transistors of the set of transistors 126-132 and each include a source connected to a cathode of a respective transistor of the set of transistors 126-132. The example set of transistors 126-132 each additionally include a gate connected to an output of a respective driver of the set of drivers 134-140.

Accordingly, the adjustable current source 122 and the adjustable current sink 124 power the drivers of the set of drivers 134-140. The drivers of the set of drivers 134-140 may additionally include one or more inputs to control the operation of the drivers. For example, the inputs may provide an indication of brightness, color, enabled/disabled, etc. and the drivers 134-140 control the transistors 126-132 to respectively control the output of the LEDs 110-116.

The example pulse generator circuitry 150 is a one-shot circuitry to generate an output pulse. Alternatively, the pulse generator circuitry 150 may be any type of element to control operation of the bypass circuitry 152 and signals the logic 158. For example, the pulse generator circuitry 150 may be an output from a controller that selectively enables the bypass circuitry 152 and signals the logic 158. The example pulse generator circuitry 150 includes an output connected to a driver input for the bypass circuitry 152 and a lock terminal of the logic circuitry 158.

The example bypass circuitry 152 is a switch that is triggered to close when the pulse generator circuitry 150 is high. Alternatively, the bypass circuitry 152 may be implemented by any other components that can bypass the LED driver 102 from the LEDs 110-116 so that the voltage at the voltage source 104 and the current sink 106 can be measured. The example bypass circuitry 152 includes a first terminal coupled to the anode of the first LED 110 and a second terminal coupled to the cathode of the fourth LED 116. When the bypass circuitry 152 is activated (e.g., the switch is closed), the first terminal is coupled to the second terminal to bypass the LED driver 102 from the LEDs 110-116.

The example first voltage detection circuitry 154 and the second voltage detection circuity 156 are comparators that compare a voltage at a first terminal, such as a positive input terminal, to a voltage at a second terminal, such as at a negative input terminal, and output a high voltage when the voltage at the positive input terminal is greater than the voltage at the negative input terminal and output a low voltage when the voltage at the positive input terminal is not greater than the voltage at the negative input terminal. The first voltage detection circuitry 154 and the second voltage detection circuitry 156 may be implemented by any other type of circuitry to determine a voltage level. While the example LED dot-controller 120 includes both the first voltage detection circuitry 154 and the second voltage detection circuitry 156, other implementations of the LED dot-controller 120 may include a single voltage detection circuitry.

In one example, the positive terminal of the first voltage detection circuitry 154 is coupled to a first end of the set of LEDs 110-116 (e.g., the anode of the first LED 110) and the negative terminal of the first voltage detection circuitry 154 is coupled to a first reference voltage. An output of the first voltage detection circuitry 154 is coupled to a first input terminal of the logic circuitry 158.

The positive terminal of the second voltage detection circuitry 156 is coupled to a second end of the set of LEDs 110-116 (e.g., the cathode of the fourth LED 116) and the negative terminal of the second voltage detection circuitry 156 is coupled to a second reference voltage. An output of the second voltage detection circuitry 156 is coupled to a second input terminal of the logic circuitry 158. According to the illustrated example, in which the switch 152 is not an ideal switch so that there is parasitic capacitance coupled in parallel with the set of LEDs 110-116 when the switch 152 is closed, the first reference voltage Vref1 is greater than the second reference voltage Vref2. In one example, Vref1−Vref2 is between 2V-3V (e.g., Vref1−Vref2=2.5V). In some situations, in which the switch 152 is an ideal switch, Vref1 and Vref2 can be configured at a same voltage level (e.g. 4V). Vref1 and Vref2 may be configured to make sure current flowing through the set of LEDs 110-116 due to the type of the LED driver can be sensed when the LED driver is disabled.

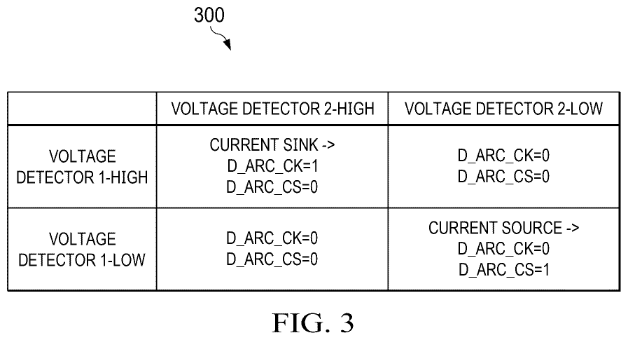

The logic circuitry 158 outputs two values (D_ARC_CS and D_ARC_CK) based on the voltages at the first input terminal and the second input terminal of the logic circuitry 158 when the lock input that is coupled to the pulse generator circuitry 150 goes high. According to the illustrated example, D_ARC_CS is set to a first logic state (e.g. logic high), to indicate that the detected circuit (e.g., the LED driver 102) is a current source type circuit and D_ARC_CK is set to a first logic state (e.g. logic high), to indicate that the detected circuit is a current sink type circuit. The logic circuitry 158 may be implemented by a digital logic circuitry (e.g., AND gates, OR gates, NOR gates, etc.). Alternatively, the logic circuitry 158 may be implemented by a controller such as a microcontroller, processor, etc. An example truth table for implementing the logic circuitry 158 is described in conjunction with FIG. 3.

The outputs of the logic circuitry are coupled to the adjustable current source 122 and the adjustable current sink 124. To avoid leakage current that causes the LEDs 110-116 to be enabled when they are intended to be disabled or otherwise not operating as expected, the example adjustable current source 122 and the example adjustable current sink 124 can be adjustable to ensure that all current within the circuit 100 is sunk to the current sink 124 and no leakage current is available to the LEDs 110-116. The amount of current to source and sink depends on the type of the LED driver 102. For the example, for the current-sink type driver 102, the amount of current sourced by the adjustable current source 122 should be greater than the amount of current sunk by the adjustable current sink 124 (e.g., N>K). For example, the adjustable current source 122 may include logic to enable additional current mirror branches when D_ARC_CK is high and D_ARC_CS is low (or other values that indicate that the LED driver 102 is a current sink-type driver).

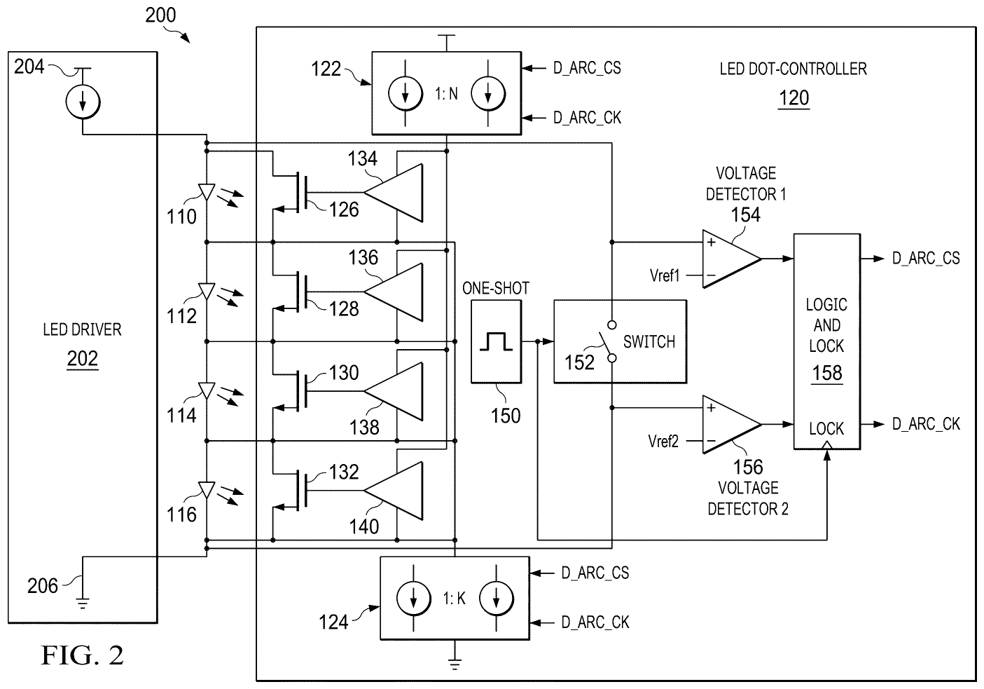

FIG. 2 illustrates another example circuit 200 for driving and controlling LEDs as disclosed herein. The example circuit 200 includes the same LEDs 110-116 and LED dot-controller 120. However, the LED driver 202 is a current source type driver circuit that includes a current source 204 and a ground connection 206. An output of the current source 204 is coupled to anode of the first LED 110 and the ground connection 206 is coupled to the cathode of the fourth LED 116.

To avoid leakage current that causes LEDs 110-116 to be incorrectly enabled, for the current-source type driver 202, the amount of current sunk by the adjustable current sink 124 should be greater than the amount of current sourced by the adjustable current source 122 (e.g., K>N). For example, the adjustable current sink 124 may include logic to enable additional current mirror branches when D_ARC_CS is high and D_ARC_CK is low (or other values that indicate that the LED driver 102 is a current source-type driver).

Accordingly, as illustrated by the example circuit 100 and the example circuit 200, the same LED dot-controller 120 can be utilized with both a current source-type LED driver or a current sink-type LED driver.

In the example of FIGS. 1-2, the transistors 126-132 are n-channel metal-oxide semiconductor field-effect transistors (MOSFETs). Alternatively, the transistors 126-132 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. The transistors 126-132 may be depletion mode devices, drain-extended devices, enhancement mode devices, natural transistors or other type of device structure transistors. Furthermore, the transistors 126-132 may be implemented in/over a silicon substrate (Si), a silicon carbide substrate (SiC), a gallium nitride substrate (GaN) or a gallium arsenide substrate (GaAs).

FIG. 3 is a truth table 300 illustrating example logic of the logic circuitry 158 of FIG. 1 and/or FIG. 2. As shown in table 300, when the first voltage detection circuit 154 indicates that the measured voltage is high (e.g., greater than the first reference voltage) and the second voltage detection circuit 156 indicates that the measured voltage is high (e.g., greater than the second reference voltage), the logic circuitry 158 determines that the connected circuit is a current sink-type detection circuit. When the first voltage detection circuit 154 indicates that the measured voltage is low (e.g., less than the first reference voltage) and the second voltage detection circuit 156 indicates that the measured voltage is low (e.g., less than the second reference voltage), the logic circuitry 158 determines that the connected circuit is a current source-type detection circuit. When the first voltage detection circuit 154 indicates that the measured voltage is high (e.g., greater than the first reference voltage) and the second voltage detection circuit 156 indicates that the measured voltage is low (e.g., less than the second reference voltage), the logic circuitry 158 outputs low for both D_ARC_CK and D_ARC_CS indicating an other/unsupported condition. When the first voltage detection circuit 154 indicates that the measured voltage is low (e.g., less than the first reference voltage) and the second voltage detection circuit 156 indicates that the measured voltage is high (e.g., greater than the second reference voltage), the logic circuitry 158 outputs low for both D_ARC_CK and D_ARC_CS indicating an other/unsupported condition.

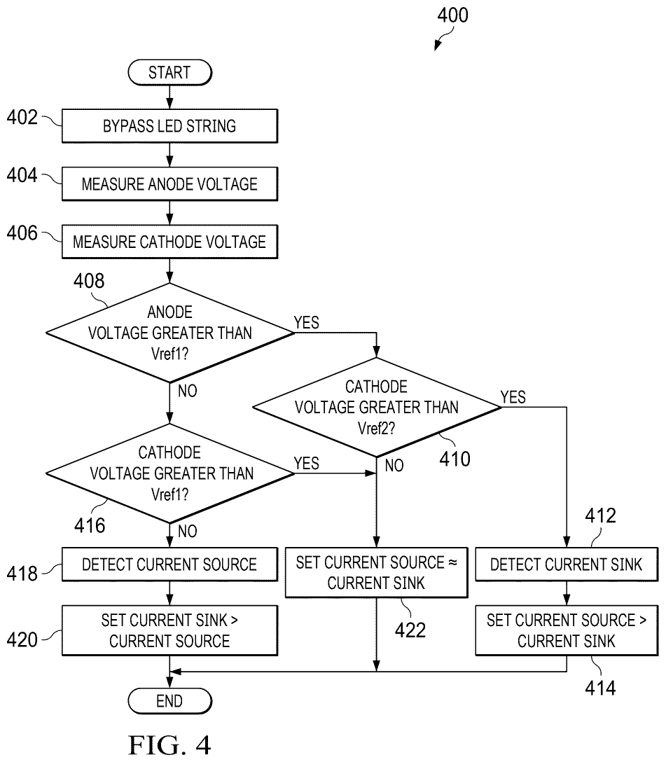

FIG. 4 is a flowchart representative of example machine-readable instructions and/or example operations 400 that may be at least one of executed, instantiated, or performed by programmable circuitry to perform circuit-type detection that may be utilized, for example, to adjust a LED controller. For example, some or all of the operations 400 may be implemented by a controller that is executing instructions, programmed by instructions, etc. The example machine-readable instructions and/or the example operations 400 of FIG. 4 begin at block 402, at which the bypass circuitry 152 bypasses the LEDs 110-116 from the LED driver 102 or 202. The first voltage detection circuitry 152 measures the voltage at a first end of the LEDs 110-116 (e.g., at the anode of the first LED 110) (block 402). The second voltage detection circuitry 154 measures the voltage at a second end of the LEDs 110-116 (e.g., at the cathode of the fourth LED 116) (block 404).

The logic circuitry 158 determines if an output of the first voltage detection circuitry 152 indicates that the voltage at the first end of the LEDs 110-116 is greater than a first reference voltage (block 408). When the voltage at the first end of the LEDs 110-116 is greater than a first reference voltage, the logic circuitry 158 determines if an output of the second voltage detection circuitry 154 indicates that the voltage at the second end of the LEDs 110-116 is greater than a second reference voltage (block 410). When the output of the second voltage detection circuitry 154 indicates that the voltage at the second end of the LEDs 110-116 is greater than a second reference voltage, the logic circuitry detects that the LED driver 102, 202 connected to the LEDs 110-116 is a current sink-type circuit (block 412) and outputs an indication that causes the adjustable current source 122 to be adjusted so that it sources more current than the adjustable current sink 124 will sink (block 414), or causes the adjustable current sink 124 to be adjusted so that it sinks less current than the adjustable current source 122 will source (block 414).

In one example, the N of the adjustable current source 122 can be configured to a first value, a second value greater than the first value, and a third value greater than the second value. Initially, N is configured to the second value. In response to the logic circuitry 158 detecting that the LED driver 102, 202 connected to the LEDs 110-116 is a current sink-type circuit (block 412), the adjustable current source 122 sets N to the third value so that it sources more current than the adjustable current sink 124 will sink (block 414), and in response to the logic circuitry 158 detecting that the LED driver 102, 202 connected to the LEDs 110-116 is a current source-type circuit (block 418), the adjustable current source 122 sets N to the first value so that it sources less current than the adjustable current sink 124 will sink (block 420).

In another example, the K of the adjustable current sink 124 can be configured to a fourth value, a fifth value greater than the fourth value, and a sixth value greater than the fifth value. Initially, K is configured to the fifth value. In response to the logic circuitry 158 detecting that the LED driver 102, 202 connected to the LEDs 110-116 is a current sink-type circuit (block 412), the adjustable current sink 124 sets K to the fourth value so that it sinks less current than the adjustable current source 122 will sink (block 414), and in response to the logic circuitry 158 detecting that the LED driver 102, 202 connected to the LEDs 110-116 is a current source-type circuit (block 418), the adjustable current sink sets K to the sixth value so that it sinks more current than the adjustable current source 122 will source (block 420). The adjustment to the adjustable current source 122 and the adjustable current sink 124 can be performed in parallel in response to the detection, or one of the adjustable current source 122 and the adjustable current sink 124 can be fixed and the other one of the adjustable current source 122 and the adjustable current sink 124 can be adjusted in response to the detection. The first through sixth values are configured to make sure that after the adjustment in response to the detection, each LED of the set of LEDs 110-116 should see zero current if the LED driver is disabled or the LED driver is configured to control the current flowing through the set of LEDs 110-116 to be zero.

Returning to block 408, when the voltage at the first end of the LEDs 110-116 is not greater than a first reference voltage, the logic circuitry 158 determines if an output of the second voltage detection circuitry 154 indicates that the voltage at the second end of the LEDs 110-116 is greater than the second reference voltage (block 416). When the output of the second voltage detection circuitry 154 indicates that the voltage at the second end of the LEDs 110-116 is not greater than the second reference voltage, the logic circuitry detects that the LED driver 102, 202 connected to the LEDs 110-116 is a current source-type circuit (block 418) and outputs an indication that causes the adjustable current sink 124 to be adjusted so that it sinks more current than the adjustable current source 122 will source (block 420).

Returning to block 416, when the output of the second voltage detection circuitry 154 indicates that the voltage at the second end of the LEDs 110-116 is greater than the second reference voltage, the logic circuitry 158 outputs an indication that causes the adjustable current sink 124 to be adjusted so that it sinks approximately the same current as the adjustable current source 122 will source.

In an ideal situation, where the switch 152 is an ideal switch, so that the voltage at the anode of the LED 110 and the voltage at the cathode of the LED 116 are same during detection when the switch 152 is closed, the first reference voltage Vref1 and the second reference voltage Vref2 are configured same with each other, e.g. 4V. In such situation, using only one of the first and second voltage detection circuities 154 and 156 is also feasible, that is, if a sensed voltage is greater than a provided reference voltage, e.g. 4V, the logic circuitry detects that the LED driver 102, 202 connected to the LEDs 110-116 is a current sink-type circuit (block 412), and if the sensed voltage is less than the provided reference voltage, e.g. 4V, the logic circuitry detects that the LED driver 102, 202 connected to the LEDs 110-116 is a current source-type circuit (block 418).

The operations 400 of FIG. 4 may executed and/or instantiated by programmable circuitry to implement all or a portion of the detection circuitry (150-158) and/or the LED dot-controller 120. The programmable circuitry can be implemented by one or more integrated circuits, logic circuits, FPGAs, microprocessors, CPUs, GPUs, DSPs, or microcontrollers from any desired family or manufacturer. The programmable circuitry may be implemented by one or more semiconductor based (e.g., silicon based) devices.

As mentioned above, the example operations of FIG. 4 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing at least one of a semiconductor device (e.g., a transistor), a semiconductor die containing a semiconductor device, or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. Semiconductor devices are often used in orientation different than their orientation during fabrication. Thus, when referring to one of or a combination of a semiconductor device (e.g., a transistor), a semiconductor die containing a semiconductor device, or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function /r other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that can detect a circuit type and/or utilize circuit type detection to configure operation of a controller such as an LED dot-controller. Described systems, apparatus, articles of manufacture, and methods improve upon prior controllers by enabling a single controller to be utilized with multiple different circuits (e.g., different types of LED driver circuits). Furthermore, disclosed controllers can adjust operation to reduce the likelihood of leakage current (e.g., leakage current flowing through LEDs). Described systems, apparatus, articles of manufacture, and methods are also directed to one or more improvement(s) in the operation of a machine such as a computer or other electronic, electromechanical, or mechanical device.

What is claimed is:

1. A detection circuitry comprising:
a bypass circuitry configured to selectively bypass a series of light emitting diodes from a light emitting diode driver;
a first voltage detection circuitry configured to compare a voltage at a first terminal of the series of light emitting diodes to a first reference voltage and output a first indication of the comparison; and
a logic circuitry configured to output a circuit type based on the first indication.

2. The detection circuitry of claim 1, further including a second voltage detection circuitry configured to compare a voltage at a second terminal of the series of light emitting diodes to a second reference voltage and output a second indication of the comparison.

3. The detection circuitry of claim 2, wherein the logic circuitry is configured to output the circuit type based on the first indication and the second indication.

4. The detection circuitry of claim 1, further including a pulse generator.

5. The detection circuitry of claim 4, wherein the pulse generator is a one-shot circuitry.

6. The detection circuitry of claim 5, wherein the bypass circuitry includes a switch controlled by the one-shot circuitry.

7. The detection circuitry of claim 6, wherein the switch is configured to couple the first terminal to a second terminal of the series of light emitting diodes.

8. A detection circuitry comprising:
a switch having a first terminal configured to be coupled to a first terminal of a series of light emitting diodes and a second terminal to be coupled to a second terminal of the series of light emitting diodes;
a first comparator having a first input terminal coupled to the second terminal of the series of light emitting diodes and a second terminal coupled to a first reference voltage;
a second comparator having a first input terminal coupled to the first terminal of the series of light emitting diodes and a second terminal coupled to a second reference voltage; and
a logic circuitry having a first input terminal coupled to an output of the first comparator, a second input terminal coupled to an output of the second comparator, and the logic circuitry configured to output an indication of a circuit type of a controller of the series of light emitting diodes.

9. The detection circuitry of claim 8, further including one-shot circuitry, the switch including a third terminal coupled to the one-shot circuitry.

10. The detection circuitry of claim 9, wherein the logic circuitry includes a lock terminal coupled to the one-shot circuitry.

11. The detection circuitry of claim 8, wherein the first terminal of the series of light emitting diodes is an anode of a first light emitting diode of the series of light emitting diodes and the second terminal of the series of light emitting diodes is a cathode of a second light emitting diode of the series of light emitting diodes.

12. The detection circuitry of claim 8, wherein the first reference voltage is greater than the second reference voltage.

13. The detection circuitry of claim 8, wherein the logic circuitry is configured to output an indication that the circuit type is current sink when first comparator indicates that a voltage at the second terminal of the series of light emitting diodes is greater than the first reference voltage.

14. The detection circuitry of claim 8, wherein the logic circuitry is configured to output an indication that the circuit type is current sink when first comparator indicates that a voltage at the second terminal of the series of light emitting diodes is less than the first reference voltage.

15. A light emitting diode controller comprising:
a current source;
a current sink;
a driver coupled to the current source and the current sink;
a transistor coupled to an output of the driver;
a switch having a first terminal to be coupled to an anode of a series of light emitting diodes and a second terminal configured to be coupled to a cathode of the series of light emitting diodes;
a first comparator having a first input terminal coupled to the cathode of the series of light emitting diodes and a second terminal coupled to a first reference voltage;
a second comparator having a first input terminal coupled to the anode of the series of light emitting diodes and a second terminal coupled to a second reference voltage; and
a logic circuitry having a first input terminal coupled to an output of the first comparator, a second input terminal coupled to an output of the second comparator, and an output to output an indication of a circuit type of a controller of the series of light emitting diodes to the current source and current sink.

16. The light emitting diode controller of claim 15, further including a light emitting diode driver coupled to the series of light emitting diodes.

17. The light emitting diode controller of claim 15, wherein the transistor includes a source coupled to the anode of the series of light emitting diodes and a drain coupled to the current sink.

18. The light emitting diode controller of claim 15, wherein the current source includes a current mirror.

19. The light emitting diode controller of claim 18, wherein the current mirror is configured to be adjusted in response to the circuit type that is output by the logic circuitry.

20. The light emitting diode controller of claim 18, wherein the current sink includes a current mirror and the current mirror of the current sink is configured to be adjusted in response to the circuit type that is output by the logic circuitry.
